(19) United States
(12) Patent Application Publication
(10) Pub. No.: US 2010/0216070 A1
(43) Pub. Date: Aug. 26, 2010

(54) Photosensitive Polyimides and Methods of Making the Same

(75) Inventors: Kazuhiro Yamanaka, Tokyo (JP); Clifford Henderson, Douglasville, GA (US); Michael Romeo, Fort Worth, TX (US); Kazuhiko Maeda, Tokyo (JP)

Correspondence Address: CANTOR COLBURN, LLP, 20 Church Street, 22nd Floor, Hartford, CT, 06103, US

(73) Assignees: CENTRAL GLASS CO., LTD., Yamaguchi (JP); GEORGIA TECH RESEARCH CORPORATION, Atlanta, GA (US)

(21) Appl. No.: 12/517,501

(22) PCT Filed: Dec. 4, 2006
(86) PCT No.: PCT/US2006/061541

§ 371 Date: Jun. 3, 2009

(51) Int. Cl. G03F 7/004; C08G 73/10

(52) U.S. Cl. 430/270.1; 528/322

(57) ABSTRACT

Photosensitive polyimide compositions include a photosensitive additive and a polymer comprising a repeating unit represented by the following formula (I): wherein R¹ comprises an aliphatic group, an alicyclic group, an aromatic group, a heterocyclic group, or combinations thereof, R² comprises an aliphatic group, an alicyclic group, an aromatic group, a heterocyclic group, or combinations thereof, R³ represents hydrogen or an organic group comprising a hydrophilic group, an acid-cleavable group, a base-cleavable group, a cross-linkable group, or combinations thereof, and h represents an integer of 1 or more. The photosensitive compositions may be formed by combining a precursor polymer with a processing solvent, followed by a relatively low-temperature cyclization process in which the precursor polymer is converted to the final polymer. The resulting polyimide may be separated from the solution and purified. It may then be combined with a casting solvent and a photosensitive additive.

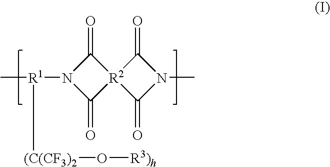

### FIELD OF THE INVENTION

The present invention generally relates to photosensitive compositions, and more particularly to photosensitive polyimides made without using high cyclization temperatures to convert precursor polymers to such polyimides, wherein the polyimides exhibit certain desirable properties such as relatively low dielectric constants.

### BACKGROUND OF THE INVENTION

Heterocyclic polymeric materials, e.g., polyimides (PIs), polybenzoxazoles (PBDs), polybenzimidazoles, and polybenzthiazoles, are widely known as high performance materials in the microelectronics field. Such materials exhibit excellent thermal stability and chemical resistance. Further, they typically exhibit relatively low dielectric constants. In addition, photosensitive versions of these materials typically possess the ability to change their solubility in response to being exposed to appropriate radiation such as ultraviolet light. Further, they are photodefinable which refers to their ability to be directly patterned using photolithography. Lithography is the process by which small structures or features, typically the size of a few microns, are patterned in a layer of material formed upon a substrate. More specifically, photolithography is the process by which most integrated circuits are patterned today and involves transferring an optical image from a patterned mask plate known as a “photomask” or “reticle” to the photosensitive material. Accordingly, such polymeric materials have commonly been used as insulation layers and passivation layers for very-large-scale-integration (VLSI) and multichip modules (MCM).

Significant research on conventional photosensitive PIs and PBOs has been reported that indicates both polymers generally may be prepared by applying a thermal cyclization process to corresponding precursor polymers, e.g., a polyamic-acid and a poly o-hydroxy amide. This thermal cyclization process refers to the conversion of a precursor polymer to its corresponding ring closed form (e.g. a polyamic-acid is converted to a polyimide or a poly o-hydroxy amide is converted to a polybenzoxazole). Due to the good solubility of the precursor polymers in various solvents, these polymers may be dissolved in suitable solvents and deposited as thin films on microelectronic substrates using simple methods such as spin casting before being thermally converted. The good solubility of the precursor polymers has also allowed such PIs and PBOs to be applied to fields other than microelectronics such as the aerospace field.

Unfortunately, the thermal cyclization process described above is typically performed at relatively high temperatures of greater than about 320° C. This high temperature treatment may lead to thermal stresses in an integrated circuit containing one or more PI or PBO layers, resulting in problems such as warpage of the integrated circuit. Further, it may also result in discoloration of PI or PBO films or other materials used in combination therewith, such as color filters, in a liquid crystal display manufacturing process. It is therefore desirable to develop photosensitive polymeric materials that can be prepared from a polymeric precursor without being subjected to high temperatures. It is further desirable that the photosensitive polymeric materials exhibit certain properties useful in their various applications such as a low dielectric constant and good solubility in various solvents.

### SUMMARY OF THE INVENTION

According to various embodiments, photosensitive compositions include a photosensitive additive and a polyimide polymer comprising a repeating unit represented by the following formula:

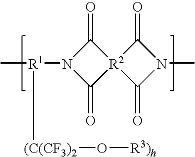

wherein R¹ comprises an aliphatic group, an alicyclic group, an aromatic group, a heterocyclic group, or combinations thereof, R² comprises an aliphatic group, an alicyclic group, an aromatic group, a heterocyclic group, or combinations thereof, R³ represents hydrogen or an organic group comprising a hydrophilic group, an acid-cleavable group, a base-cleavable group, a cross-linkable group, or combinations thereof, and h represents an integer of 1 or more. Examples of suitable polymers are described in International Patent Application Nos. WO/2006/043501 and WO/2006/041115, which are incorporated by reference herein in their entirety. These exemplary polymers exhibit very useful properties, including water repellency, oil repellency, low water absorption, heat resistance, corrosion resistance, high transparency, low refractive index, and low dielectric constants. Further, they may be formed via a low thermal cyclization temperature of less than 300° C.

The aforementioned photosensitive additive may comprise, for example, a photosensitive dissolution inhibitor, a photoacid generator, a photobase generator, a photo-free radical generator, or combinations thereof. Such photosensitive compositions are advantageously soluble in various developer solutions and may serve as either positive or negative tone photodefinable films. As photodefinable films, they may be formed into relief patterns that exhibit certain desirable properties such as relatively low dielectric constants.

In more embodiments, methods of forming the foregoing photosensitive compositions include first forming a precursor polymer comprising a repeating unit represented by the following formula:

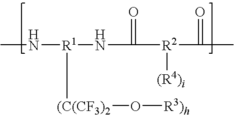

wherein R¹ comprises an aliphatic group, an alicyclic group, an aromatic group, a heterocyclic group, or combinations thereof, R² comprises an aliphatic group, an alicyclic group, an aromatic group, a heterocyclic group, or combinations thereof, R³ represents hydrogen or an organic group comprising a hydrophilic group, an acid-cleavable group, a base-cleavable group, a cross-linkable group, or combinations thereof, R⁴ comprises a hydrophilic group, a hydrophilic group protected by an acid-cleavable group, a hydrophilic group protected by a base-cleavable group, a hydrophilic group protected by a cross-linkable group, or combinations thereof, h represents an integer of 1 or more, and i represents an integer of 0, 1, or more. The precursor polymer may then be combined with a processing solvent to form a precursor solution, followed by a cyclization process in which the precursor polymer is converted to the final polymer. In one embodiment, the cyclization process involves heating the precursor solution at a thermal processing temperature in the range of from about 180° C. to about 320° C. In alternative embodiments, the cyclization process involves treating the precursor solution with an acid catalyst or a dehydration agent. The resulting polyimide polymer may subsequently be separated from the solution and purified. It may then be combined with a casting solvent and a photosensitive additive to complete the formation of the photosensitive composition.

The cyclization process advantageously avoids exposing the polyimide polymers to high temperatures that could otherwise damage the polymers. Further, the photosensitive composition may be used for various applications without being concerned that high heat exposure could cause problems for those applications. For example, the photosensitive compositions may be employed as photodefinable films upon layers of an integrated circuit without subjecting the films to high thermal processing temperatures that could compromise the integrity of the circuit.

### BRIEF DESCRIPTION OF THE DRAWINGS

FIG. 1 is a plot of the film thickness (FT) as a function of the developing time of a photodefinable film comprising hexafluoroalcohol-substituted orthodiamine polyimide (HFA-ODA-PI), which is developed using a tetramethylammonium hydroxide (TMAH) aqueous developer.

FIG. 2a is an optical micrograph of photolithography patterns obtained in 20 weight % trihydroxybenzophenone-loaded HFA-ODA-PI films using a bright field mask.

FIG. 2b is an optical micrograph of photolithography patterns obtained in 20 weight % trihydroxybenzophenone-loaded HFA-ODA-PI films using a dark field mask.

FIG. 3 is a plot of the absorbance of a HFA-ODA-PI film as a function of the wavelength of radiation applied to the film.

### DETAILED DESCRIPTION OF THE PREFERRED EMBODIMENTS

In accordance with various embodiments, photosensitive compositions include: (a) a polyimide (PI) polymer comprising a repeating unit generally represented by the following formula:

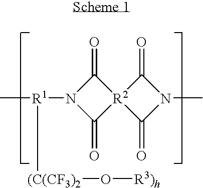

wherein R¹ comprises an aliphatic group, an alicyclic group, an aromatic group, a heterocyclic group, or combinations thereof, R² comprises an aliphatic group, an alicyclic group, an aromatic group, a heterocyclic group, or combinations thereof, R³ represents hydrogen or an organic group comprising a hydrophilic group, an acid-cleavable group, a base-cleavable group, a cross-linkable group, or combinations thereof, and h represents an integer of 1 or more; and
(b) a photosensitive additive, which differentiates the dissolution rates in a developing solution of areas of the photosensitive compositions exposed and unexposed to actinic light irradiation to allow the formation of a relief pattern.

In various embodiments of the PI polymer, R³ in scheme 1 is represented by the following formula:

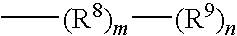

wherein R⁸ represents an organic group comprising from 1 to 40 carbon atoms, R⁹ comprises a hydrophilic group, a hydrophilic group protected by an acid-cleavable group, a hydrophilic group protected by a base-cleavable group, a hydrophilic group protected by a cross-linkable group, or combinations thereof, m represents an integer of 0 or 1, and n represents an integer of 1 or more. For example, R⁹ may be represented by one of the following formulas:

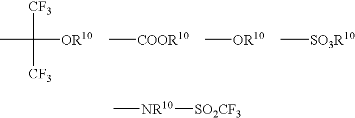

wherein R¹⁰ represents hydrogen or an organic group comprising an acid-cleavable group, a base-cleavable group, a cross-linkable group, or combinations thereof. For example, R¹⁰ may be represented by one of the following formulas:

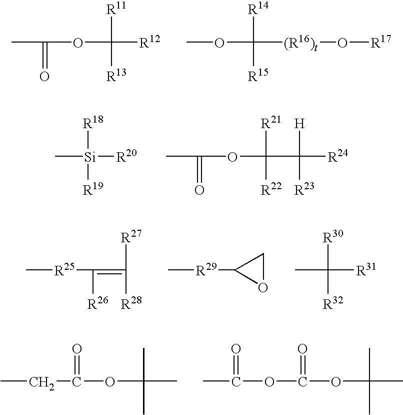

wherein R¹¹, R¹², and R¹³ each represents hydrogen or an organic group comprising from 1 to 40 carbon atoms, R¹⁴ and R¹⁵ each represents hydrogen or an organic group comprising from 1 to 40 carbon atoms, R¹⁶ and R¹⁷ each represents an organic group comprising from 1 to 40 carbon atoms, t represents an integer of 0 or 1, R¹⁸, R¹⁹, and R²⁰ each represents an organic group comprising from 1 to 40 carbon atoms, R²¹, R²², R²³, and R²⁴ each represents hydrogen or an organic group comprising from 1 to 40 carbon atoms, R²⁵ represents an organic group comprising from 1 to 40 carbon atoms, R²⁶, R²⁷, and R²⁸ each represents hydrogen or an organic group comprising from 1 to 40 carbon atoms, R²⁹ represents an organic group comprising from 1 to 40 carbon atoms, and R³⁰, R³¹, and R³² each represents hydrogen or an organic group comprising from 1 to 40 carbon atoms.

In more embodiments of the PI polymer, R¹—(C(CF₃)₂—O—R³)ₕ in scheme 1 is represented by the following formula:

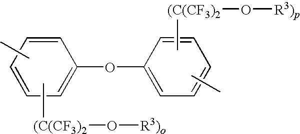

wherein o and p each represents an integer of 0, 1, 2, 3, or 4 and o+p>0. In addition, R² in scheme 1 is represented by the following formula:

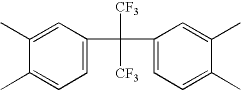

In yet more embodiments of the PI polymer, R¹—(C(CF₃)₂—O—R³)ₕ in scheme 1 is represented by the following formula:

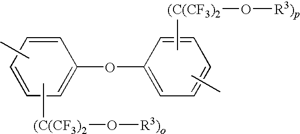

wherein o and p each represents an integer of 0, 1, 2, 3, or 4, o+p>0, and R² is represented by the following formula:

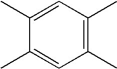

In additional embodiments of the PI polymer, R¹—(C(CF₃)₂—O—R³)ₕ in scheme 1 is represented by the following formula:

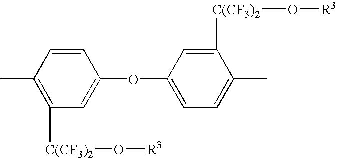

wherein R³ represents hydrogen or an organic group represented by one of the following formulas:

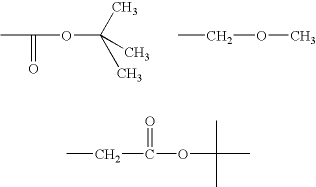

As mentioned above, the photosensitive compositions may include one or more photosensitive additives. The photosensitive additive serves to differentiate the alkali solubility of the exposed region of the PI polymer from that of the non-exposed region. Distinct photosensitive additives have different absorption wavelengths. Therefore, by using distinct actinic lights corresponding to the different photosensitive additives, a pattern can be formed in the photosensitive composition by distinct stages.

In various embodiments, the photosensitive additive may be a photosensitive dissolution inhibitor, which suppresses the alkali solubility of the PI polymer in the absence of actinic light. However, when actinic light is irradiated upon the PI polymer in the presence of this type of photosensitive additive, an alkali soluble moiety is formed. Thus, the exposed region becomes soluble in an alkali solution, whereas the non-exposed region is still insoluble in the alkali solution. Therefore, the combination of the PI polymer and this type of photosensitive additive forms a positive tone photodefinable film. Examples of such dissolution inhibitors include but are not limited to diazonium salts, o-diazoquinones (o-quinone diazides) such as o-diazonaphthoquinones (DNQ), diazoquinone sulphonamides, diazoquinone sulphonic acid esters, and diazoquinone sulphonates, and combinations thereof.

The o-diazoquinone compound may be obtained, for example, by a condensation reaction of an o-quinonediazide sulphonyl chloride with a polyhydroxy compound, a polyamine compound, or a polyhydroxy polyamine compound. Examples of o-quinonediazide sulphonyl chloride compounds include but are not limited to 1,2-benzoquinone-2-azido-4-sulphonyl chloride, 1,2-naphthoquinone-2-diazido-5-sulphonyl chloride, 1,2-naphthoquinone-2-diazido-6-sulphonyl chloride, 1,2-naphthoquinone-2-diazido-4-sulphonyl chloride, and combinations thereof. Examples of polyhydroxy compounds include but are not limited to hydroquinone, resorcinol, pyrogallol, bisphenol A, bis(4-hydroxyphenyl)methane, 2,2-bis(4-hydroxyphenyl)hexafluoropropane, 2,3,4-trihydroxybenzophenone, 2,3,4-trihydroxy diphenyl methane, 2,3,4,4′-tetrahydroxy diphenyl methane 2,3,4,4′-tetrahydroxybenzophenone, 2,2′,4,4′-tetrahydroxybenzophenone, tris(4-hydroxyphenyl)methane, 1,1,1-tris(4-hydroxyphenyl)ethane, 1-[1-(4-hydroxyphenyl)isopropyl]-[1,1-bis(4-hydroxyphenyl)ethyl]benzene, 1-naphthol, 2-naphthol, methyl gallate, ethyl gallate, and combinations thereof. Examples of polyamine compounds include but are not limited to 1,4-phenylenediamine, 1,3-phenylenediamine, 4,4′-diaminodiphenyl ether, 4,4′-diaminodiphenylmethane, 4,4′-diaminodiphenylsulphone, 4,4′-diaminodiphenylsulphide, and combinations thereof. Examples of polyhydroxy polyamine compounds include but are not limited to 2,2-bis(3-amino-4-hydroxyphenyl)hexafluoropropane, 3,3-dihydroxybenzidine, and combinations thereof.

Specific examples of o-diazoquinone compounds include but are not limited to 1,2-benzoquinone-2-azido-4-sulphonate ester or sulphonamide, 1,2-napththoquinone-2-diazido-5-sulphonate ester or sulphonamide, 1,2-naphthoquinone-2-diazido-4-sulphonate ester or sulphonamide, and combinations thereof. The amount of o-diazoquinone included in the photosensitive composition may be in the range of from about 0.01% to about 40%, alternatively in the range of from about 5% to about 30%, or alternatively in the range of from about 15% to about 25%, these percentages being by weight of the total solids.

In more embodiments, the photosensitive additive may be one or more photoacid generators. A photoacid generator generates an acid when it is exposed to actinic light. Examples of suitable photoacid generators include but are not limited to onium salts, sulfonate esters, disulfonyldiazomethanes, nitrobenzyl esters, vicinal halides, halogenated isocyanates, triazine halides, disulphones, and combinations thereof. The combination of the PI precursor polymer and the photoacid generator forms a positive tone photodefinable film. The amount of photoacid generator included in the photosensitive composition may be in the range of from about 0.01% to about 20%, alternatively in the range of from about 0.5% to about 10%, or alternatively in the range of from about 1% to about 7%, these percentages being by weight of the total solids.

In yet more embodiments, the photosensitive additive may be one or more photobase generators. A photobase generator generates a base when it is exposed to actinic light. The photobase generator may be, for example, a cobalt amine complex as represented by Co(III)(RNH₂)₅X²⁺, wherein R represents hydrogen or an alkyl group comprising 1 or more carbon atoms and X represents Br⁻ or Cl⁻. Other examples of suitable photobase generators include but are not limited to oxime esters, carbamic acids, nitrobenzyl sulfonamides, quaternary ammonium salts, and combinations thereof. The combination of the PI precursor polymer and the photobase generator forms a positive tone photodefinable film. The amount of photobase generator included in the photosensitive composition may be in the range of from about 0.01% to about 20%, alternatively in the range of from about 0.5% to about 10%, or alternatively in the range of from about 1% to about 7%, these percentages being by weight of the total solids.

In still more embodiments, the photosensitive additive may be one or more photo-free radical generators. A photo-free radical generator generates a radical when it is exposed to actinic light. Examples of suitable photo-free radical generators include but are not limited to benzoin ethers, benzyl derivatives, trichlorotriazines, phosphine oxides, and combinations thereof. The amount of photo-free radical generator included in the photosensitive composition may be in the range of from about 0.01% to about 20%, alternatively in the range of from about 1% to about 10%, or alternatively in the range of from about 3% to about 7%, these percentages being by weight of the total solids.

The photosensitive compositions may optionally include one or more photosensitizers. In particular, if the photosensitive composition as prepared is transparent to the wavelength of the actinic light, a photosensitizer may be useful. The photosensitizer is desirably capable of receiving the energy of the actinic light and transferring it to the photosensitive additive. Thus, the particular photosensitive additive present in the photosensitive composition influences the choice of the photosensitizer. Examples of suitable photosensitizers include but are not limited to aromatic compounds such as naphthalenes, anthracenes, and pyrenes, carbazole derivatives, aromatic carbonyl compounds, benzophenone derivatives, thioxanthone derivatives, coumarin derivatives, and combinations thereof. Specific examples of suitable photosensitizers include but are not limited to 1-methylnaphthalene, 2-methylnaphthalene, 1-fluoronaphthalene, 1-chloronaphthalene, 2-chloronaphthalene, 1-bromonaphthalene, 2-bromonaphthalene, 1-iodinenaphthalene, 2-iodinenaphthalene, 1-naphthol, 2-naphthol, 1-methoxynaphthalene, 2-methoxynaphthalene, 1,4-dicyanonaphthalene, anthracene, 1,2-benzanthracene, 9,10-dichloroanthracene, 9,10-dibromoanthracene, 9,10-diphenylanthracene, 9-cyanoanthracene, 9,10-dicyanoanthracene, 2,6,9,10-tetracyanoanthracene, carbazole, 9-methylcarbazole, 9-phenylcarbazole, 9-propyl-9H-carbazole, 9-vinylcarbazole, 9H-carbazole-9-ethanol, 9-methyl-3-nitro-9H-carbazole, 9-methyl-3,6-dinitro-9H-carbazole, 9-carbazole methanol, 9-carbazole propionic acid, 9-decyl-3,6-dinitro-9H-carbazole, 9-ethyl-3,6-dinitro-9H-carbazole, 9-ethyl-3-nitrocarbazole, 9-ethylcarbazole, 9-isopropylcarbazole, 9-(ethoxycarbonylmethyl)carbazole, 9-(morpholinomethyl)carbazole, 9-acetylcarbazole, 9-arylcarbazole, 9-benzyl-9H-carbazole, 9-carbazole acetic acid, 9-(2-nitrophenyl)carbazole, 9-(4-methoxyphenyl)carbazole, 9-(1-ethoxy-2-methyl-propyl)-9H-carbazole, 3-nitrocarbazole, 4-hydroxycarbazole, 3,6-dinitro-9H-carbazole, 3,6-diphenyl-9H-carbazole, 2-hydroxycarbazole, 3,6-diacetyl-9-ethylcarbazole, benzophenone, 4-phenylbenzophenone, 4,4′-bis(dimethoxy)benzophenone, 4,4′-bis(dimethylamino)benzophenone, 4,4′-bis(diethylamino)benzophenone, 2-benzoylbenzoic acid methyl ester, 2-methylbenzophenone, 3-methylbenzophenone, 4-methylbenzophenone, 3,3′-dimethyl-4-methoxybenzophenone, 2,4,6-trimethylbenzophenone, [4-(4-methylphenylthio)phenyl]-phenylmethanone, xanthone, thioxanthone, 2-chlorothioxanthone, 4-chloro thioxanthone, 2-isopropyl thioxanthone, 4-isopropyl thioxanthone, 2,4-dimethyl thioxanthone, 2,4-diethyl thioxanthone, 1-chloro-4-propoxy thioxanthone, and combinations thereof. The amount of photosensitizer included in the photosensitive composition may be in the range of from about 0.01% to about 20%, alternatively in the range of from about 0.5% to about 10%, or alternatively in the range of from about 1% to about 7%, these percentages being by weight of the total solids.

Optionally, the photosensitive compositions also may include one or more thermal acid generators. A thermal acid generator generates an acid when it is exposed to heat but not when it is exposed to light. After the development of a relief pattern in the photosensitive composition, it is usually heated, causing the thermal acid generator to generate acid which in turn assists in the cleavage of the acid-cleavable group. Examples of suitable thermal acid generators include but are not limited to halogenoid nitrogen-containing compounds that generate a halogen radical when exposed to heat, sulfonate esters such as nitrobenzyl sulfonates, and combinations thereof. The amount of thermal acid generator included in the photosensitive composition may be in the range of from about 0.01% to about 20%, alternatively in the range of from about 0.5% to about 10%, or alternatively in the range of from about 1% to about 7%, these percentages being by weight of the total solids.

In addition, one or more cross-linkers optionally may be added to the photosensitive compositions. The cross-linker causes a cross-linking reaction such that regions of the photosensitive composition exposed to actinic light become insoluble in an alkali solution. Therefore, the combination of the PI polymer, a cross-linker, and a photoacid generator or a photobase generator forms a negative tone photodefinable film. When the acid-cleavable group, base-cleavable group, thermal cleavable group and/or hydrophilic group remain after forming a relief pattern in the photosensitive composition, the cross-linker may react with these groups. As a result of this reaction by the cross-linker, certain properties, e.g., the tensile strength, of the relief pattern may be modified. For example, if a hydrophilic group such as a hydroxyl group or carboxyl group is generated at the portion where R³ is cleaved off, the cross-linker can react with the generated hydrophilic group. It is to be understood that as used herein, the term “cross-linker” refers to a compound that is different from a cross-linkable group included in the PI polymer. The cross-linker may include compounds which have two or more epoxy groups, vinyl ether groups, acrylate groups, methacrylate groups, methylol groups, alkoxymethyl groups, or combinations thereof. Examples of suitable cross-linkers include but are not limited to bisphenol A epoxy resins, bisphenol F epoxy resins, bisphenol AD epoxy resins, cresol novolac epoxy resins, phenol novolac epoxy resins, glycidyl amine epoxy resins, polysulfide epoxy resins, dimethylol ureas, alkoxy methyl melamines, and combinations thereof. The amount of cross-linker included in the photosensitive composition may be in the range of from about 0.01% to about 40%, alternatively in the range of from about 0.1% to about 20%, or alternatively in the range of from about 1% to about 10%, these percentages being by weight of the total solids.

One or more casting solvents also may be included in the photosensitive compositions to dissolve or homogenously disperse the components therein. Examples of suitable solvents include but are not limited to organic solvents such as amides, ether esters, ketones, esters, glycol ethers, hydrocarbons, aromatic hydrocarbons, fluorinated solvents, alcohols, carbonates, and combinations thereof. More specific examples of organic solvents include but are not limited to N,N-dimethyl formamide (DMF), gamma(γ)-butyrolactone (GBL), propylene glycol methyl ether (PGME), propylene glycol methyl ether acetate (PGMEA), tetrahydrofuran (THF), 1-methyl-2-pyrrolidinone(NMP), N,N-dimethylacetamide (DMAC), cyclohexanone methanol, acetone, and combinations thereof.

The photosensitive compositions may be prepared by first synthesizing a poly(amic-acid) polymer, also known as the PI precursor polymer, via polymerization of a substituted organic diamine compound (e.g., hexafluoroisopropanol-substituted orthodiamine (HFA-ODA)) and a dianhydride compound (e.g., hexafluoro diamine (6FDA)). The PI precursor polymer may then be dissolved in a processing solvent such as DMF, NMP, GBL, PGMEA, and combinations thereof, thereby forming a processing solution. The PI precursor polymer further may be converted into the PI polymer via a cyclization process that avoids exposing the PI precursor polymer to high temperatures above about 320° C. This cyclization process may be performed by various methods that accelerate dehydration of the PI precursor polymer. In various embodiments, the cyclization process comprises heating the processing solution at a thermal processing temperature in the range of from about 180° C. to about 320° C., preferably in the range of from about 250° C. to about 300° C. This heating step may be performed for a period of from about 0.5 hour to about 5 hours, preferably from about 1 hour to about 3 hours. In alternative embodiments, the cyclization process is performed using solution imidization. For example, the processing solution may be treated with an acid catalyst such as a hydrochloric acid aqueous solution having a molarity of from about 1 M (molar) to about 12 M. Alternatively, the processing solution may be treated with a dehydration agent such as acetic anhydride, acetyl chloride, or combinations thereof. By avoiding the use of high temperatures to form the PI polymer, the polymer and surrounding materials, such as layers of an integrated circuit, may be protected from damaging thermal stresses. Subsequent to forming the PI polymer, it may be separated from the reaction liquid by, e.g., precipitation, and then purified by, e.g., filtration. Preparation of the photosensitive compositions further includes combining the PI polymer with one or more photosensitive additives and a suitable casting solvent as described above.

The photosensitive compositions described herein are photodefinable and thus may be patterned using photolithography. In particular, photolithography entails first coating a layer of an ensuing integrated circuit with the photosensitive composition via spin coating, spray coating, or roller coating. The layer of the integrated circuit may comprise, for example, a conductive or dielectric layer residing upon a semiconductor substrate such as a silicon substrate or ceramic or gallium arsenide substrate. Generally, the photosensitive composition is applied such that after being dried it has a film thickness of from about 0.1 μm (micrometer) to about 300 μm. The drying process generally may be carried out at a temperature of from about 50° C. to about 150° C. for a period of 1 minute to several hours.

The photolithography steps further include placing a reticle with a desired pattern adjacent to the photosensitive film and passing actinic light through transparent regions of the reticle to the photosensitive film. Other regions of the reticle block the light, thereby preventing it from reaching underlying regions of the photosensitive film. The reticle may be aligned to underlying structures of the integrated circuit before exposing the photosensitive film. Alternatively, the use of a laser beam via a direct write process may be employed to eliminate the process of applying the reticle. By exposing the photosensitive film to light, the alkali solubility of the exposed portion becomes differentiated from the non-exposed portion. Generally, an actinic light which has a wavelength sensitive to the photosensitive additive may be used. Examples of suitable actinic light radiation include but are not limited to ultraviolet light, far ultraviolet light, infrared light, an electron beam, X-rays, and the like. For example, 248 nm (KrF line), 308 nm, 365 nm (I-line), 405 nm (H-line), 436 nm (G-line), and 488 nm radiation may be used.

Subsequently, the photosensitive film may be subjected to a development process. As mentioned previously, it may serve as either a positive or a negative tone photodefinable material because it becomes more or less soluble in a developing solution (“developer”) when exposed to actinic light. In the case of a positive tone material, the exposed regions may be removed by dissolving them in a developer. In the case of a negative tone material, the non-exposed regions may be removed by dissolving them in a developer. In one embodiment, the developer may be an alkaline aqueous solution, which includes a base component such as tetramethylammonium hydroxide (TMAH), diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, cyclohexylamine, ethylenediamine, hexamethylenediamine, and combinations thereof. The molarity of the alkaline aqueous solution may be, for example, in the range of from about 0.5% to about 6%. In an alternative embodiment, the developer may be an organic solution. Examples of suitable organic solutions include but are not limited to the following: polar solvents such as N-methyl-2-pyrrolidone (NMP), N,N-dimethylformamide, N,N-dimethylacetamide, dimethylsulphoxide, γ-butyrolactone, and dimethylacrylamide; alcohols such as methanol, ethanol, and isopropanol; esters such as ethyl lactate and propylene glycol monomethyl ether acetate; ketones such as cyclopentanone, cyclohexanone, isobutyl ketone, and methyl isobutyl ketone; and combinations thereof. As a result of the development process, a relief pattern is formed in the photosensitive film. Following development, the photosensitive film may be rinsed with water.

The photosensitive PI polymer compositions described herein exhibit certain properties that make them useful in various applications. For example, they exhibit relatively low dielectric constant values. In various embodiments, their dielectric constant values are in the range of from about 2.5 to about 3.5. In alternative embodiments, their dielectric constant values are in the range of from about 2.7 to about 3.0. The photosensitive PI polymer compositions also exhibit good coefficient of thermal expansion (CTE) values. In various embodiments, they exhibit CTE values in the range of from about 10 parts per million/Kelvin (ppm/K) to about 100 ppm/K. In alternative embodiments, they exhibit CTE values in the range of from about 20 ppm/K to about 50 ppm/K. In addition, these compositions exhibit desirable absorbance values. In various embodiments, they exhibit absorbance values in the range of from about 0.01 to about 1.0 μm⁻¹ for I-line radiation, in the range of from about 0.01 to about 1.0 μm⁻¹ for H-line radiation, and in the range of from about 0.005 to about 1.0 μm⁻¹ for G-line radiation.

These properties allow the PI polymer compositions to serve as passivation and isolation layers in integrated circuits. Because the PI polymer compositions are photodefinable, they may be patterned into structures of an integrated circuit using photolithography. Due to their ability to resist being removed by a chemical etchant, the PI polymer compositions also may serve as photoresist layers that protect underlying layers of integrated circuits from being removed. Moreover, they may serve as liquid crystal orienting films in liquid crystal display devices without the need to use high thermal processing temperatures that could discolor them or surrounding materials such as color filters. Other uses of the PI polymer compositions would be obvious to one skilled in the art.

The PI precursor polymer mentioned above may comprise a repeating unit as represented by the following formula:

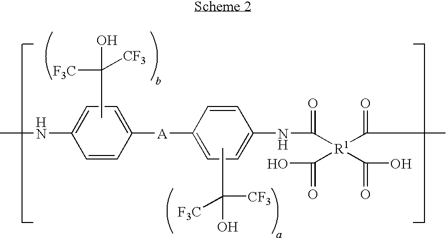

wherein A comprises nothing, oxygen, sulfur, nitrogen, or fluorine, a and b each represents an integer of 1, 2, 3, or 4, and R¹ comprises an alicyclic, aromatic, alkyl, or heterocyclic group substituted with nothing, an alkyl group, a fluoroalkyl group, a carboxyl group, a hydroxyl group, a cyano group, or combinations thereof. According to one particular embodiment, a=1, b=1, A is oxygen, and R¹ is represented by the following formula:

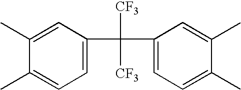

The PI precursor polymer also may be combined with one or more photosensitive additives and a casting solvent to form a photosensitive composition. The photosensitive additives, casting solvents, and relative amounts described above in relation to the PI polymer compositions also may be applied to photosensitive PI precursor compositions. One or more photosensitizers, thermal acid generators, and/or cross-linkers like those described above also may be included in such PI precursor compositions. Positive and negative photodefinable films may be formed from the PI precursor compositions using the photolithography method described above. For example, a PI precursor composition containing an o-diazoquinone such as DNQ, a photoacid generator, or a photobase generator may form a positive tone photodefinable film. Moreover, a PI precursor polymer containing a cross-linker and a photoacid generator or a photobase generator may form a negative tone photodefinable film. In addition, the PI precursor compositions may serve as photoresist layers.

An example of the synthesis of a specific PI polymer that contains hexafluoroisopropanol groups is given below:

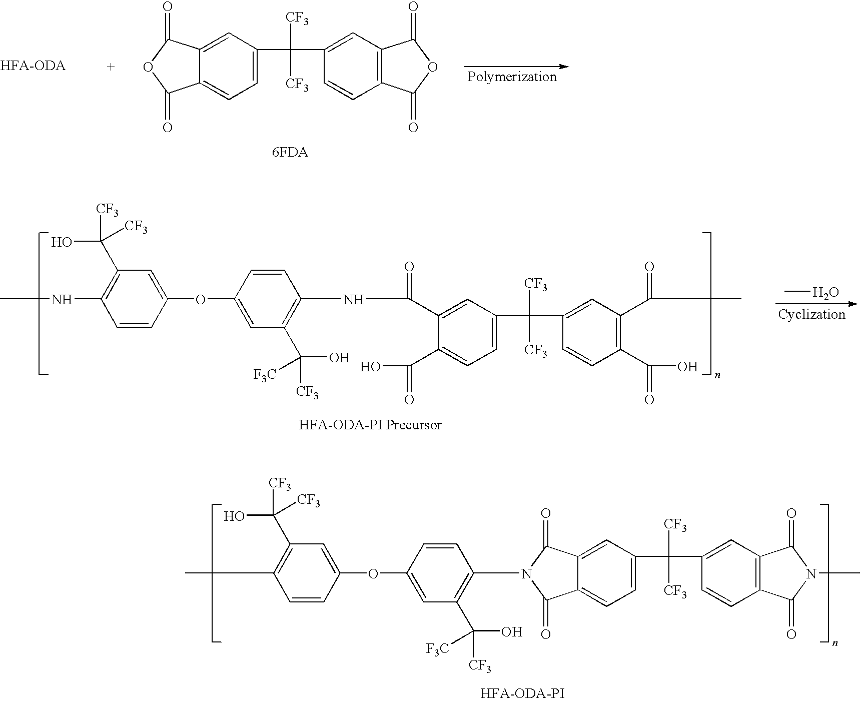

where n represents the degree of polymerization and HFA-ODA is represented by the following formula:

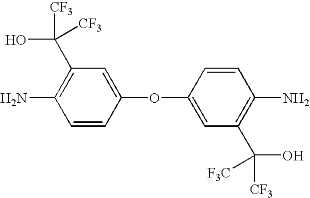

The polyimide compositions described herein may be copolymerized with polybenzoxazine compositions like those described in the U.S. Patent entitled “Photosensitive Polybenzoxazines and Methods of Making the Same,” concurrently filed herewith and incorporated by reference herein. Such poly(benzoxazine-co-imide)s may be represented by the following formula:

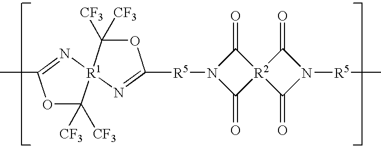

wherein R¹ comprises an aliphatic group, an alicyclic group, an aromatic group, a heterocyclic group, or combinations thereof, R² comprises an aliphatic group, an alicyclic group, an aromatic group, a heterocyclic group, or combinations thereof, and R⁵ comprises an aliphatic group, an alicyclic group, an aromatic group, a heterocyclic group, or combinations thereof. In various embodiments, R⁵ may be represented by the following formula:

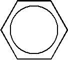

Precursor copolymers of the poly(benzoxazine-co-imide)s may be represented by one of the following formulas:

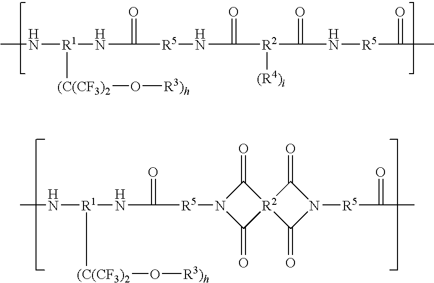

wherein R¹ comprises an aliphatic group, an alicyclic group, an aromatic group, a heterocyclic group, or combinations thereof, R² comprises an aliphatic group, an alicyclic group, an aromatic group, a heterocyclic group, or combinations thereof, R³ represents hydrogen or an organic group comprising a hydrophilic group, an acid-cleavable group, a base-cleavable group, a cross-linkable group, or combinations thereof, R⁴ comprises a hydrophilic group, a hydrophilic group protected by an acid-cleavable group, a hydrophilic group protected by a base-cleavable group, a cross-linkable group, or combinations thereof, R⁵ comprises an aliphatic group, an alicyclic group, an aromatic group, a heterocyclic group, or combinations thereof, h represents an integer of 1 or more, and i represents an integer of 0, 1, or more. The precursor copolymers also may be combined with one or more photosensitive additives and a casting solvent to form photosensitive compositions in the same manner described above in relation to the PI polymer compositions. One or more photosensitizers, thermal acid generators, and/or cross-linkers like those described above also may be included in such precursor copolymer compositions. Positive and negative photodefinable films may be formed from the precursor copolymer compositions.

An example of the conversion of a specific precursor copolymer to a specific poly(benzoxazine-co-imide) is provided below:

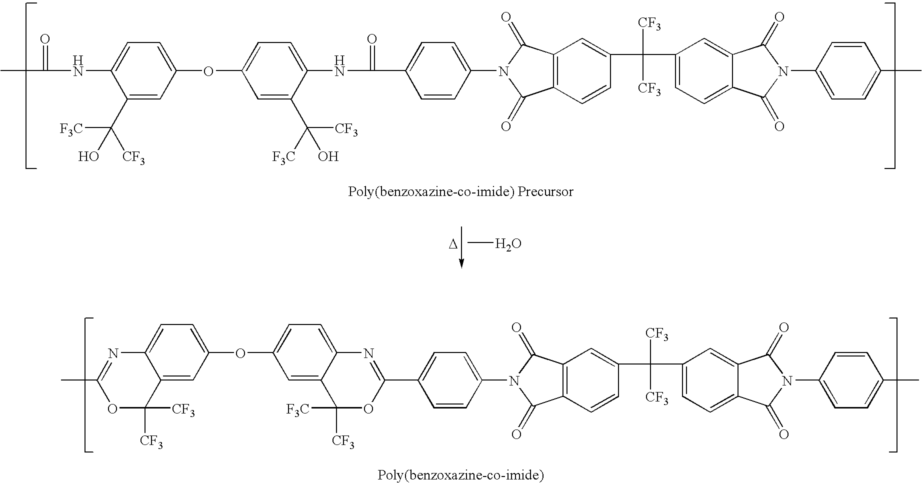

### Examples

The invention having been generally described, the following examples are given as particular embodiments of the invention and to demonstrate the practice and advantages thereof. It is understood that the examples are given by way of illustration and are not intended to limit the specification or the claims to follow in any manner.

### Example 1

The following HFA-ODA starter compound was provided:

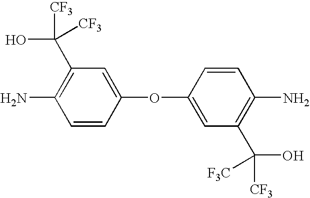

In a three-neck flask having a volume of 300 milliliters (mL), 1.50 grams (g) of the HFA-ODA starter compound, 1.25 g of 2,2-bis(3,4-dicarboxyphenyl)hexafluoropropanoic acid dianhydride (6FDA), and 11 mL of NMP were mixed for a period of 5 hours at room temperature in a N₂ atmosphere. The reaction liquid was combined with methanol and water, thereby precipitating a polymer. The polymer as precipitated was collected by filtration and then subjected to vacuum drying at a temperature of 50° C. The yield of the reaction was 98% by weight of the starter compound (2.70 g). Then the polymer was dissolved in NMP solvent such that its concentration in the solvent was 0.5 g/dL (deciliter). The intrinsic viscosity of the polymer solution at 25° C. as measured by an Ostwald viscometer was 0.13 dL/g. The results of nuclear magnetic resonance (NMR) and infrared (IR) spectroscopy indicated that a PI precursor polymer comprising the following repeating units had been formed:

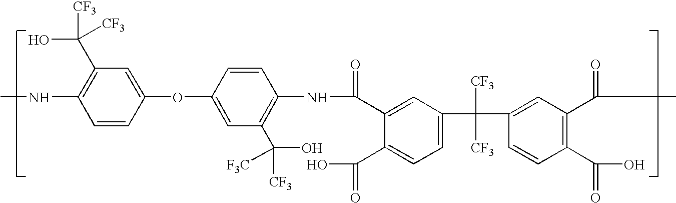

### Example 2

In a three-neck flask having a volume of 300 mL, 5.00 g of the HFA-ODA starter compound, 4.17 g of 6FDA, and 37 mL of NMP were mixed for a period of 5 hours at room temperature in a N₂ atmosphere. The reaction liquid was then mixed for a period of 16 hours at 200° C. in a N₂ atmosphere. Sometime during this period, the PI precursor polymer formed in the reaction liquid was converted to the final PI polymer. Thereafter, the resulting reaction liquid was combined it with methanol and water, thereby precipitating a polymer. The polymer as precipitated was collected by filtration and then subjected to vacuum drying at a temperature of 50° C. The yield of the reaction was 99% by weight of the starter compound (8.76 g). Then the polymer was dissolved in NMP solvent such that its concentration in the solvent was 0.5 g/dL. The intrinsic viscosity of the polymer solution at 25° C. as measured by an Ostwald viscometer was 0.19 dL/g. The results of NMR and IR spectroscopy indicated that a PI polymer comprising the following repeating units had been formed:

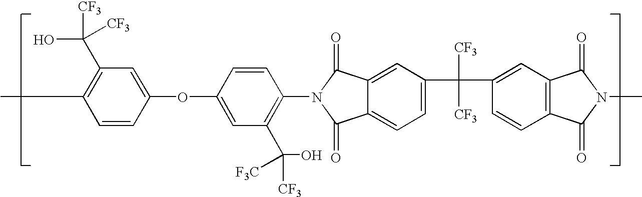

The PI polymer exhibited good solubility in DMF, γ-GBL, THF, PGMEA, and 0.25 normality (N) TMAH aqueous solution. Using a UV-VIS spectrometer, the absorbance value of the PI polymer was determined to be 0.03 μm as measured with ultraviolet light having a wavelength of 365 nm. The dielectric constant value of the PI polymer as measured at a frequency of 1 megaHertz (MHz) was determined to be 3.06.

### Example 3

In a three-neck flask having a volume of 300 mL, 1.00 g of the PI precursor polymer obtained in Example 1, 0.21 g of acetic anhydride, 0.18 g of pyridine, and 5 mL of DMF were mixed for a period of 16 hours at 100° C. in a N₂ atmosphere. The reaction liquid was then combined with methanol and water, thereby precipitating a polymer. The polymer as precipitated was collected by filtration and then subjected to vacuum drying at a temperature of 50° C. The yield of the reaction was 89% by weight of the PI precursor polymer (0.86 g). Then the polymer was dissolved in NMP solvent such that its concentration in the solvent was 0.5 g/dL. The intrinsic viscosity of the polymer solution at 25° C. as measured by an Ostwald viscometer was 0.14 dL/g. The results of NMR and IR spectroscopy indicated that a PI polymer having the same structure as that formed in Example 2 had been created.

### Example 4

In a three-neck flask having a volume of 300 mL, 1.40 g of the HFA-ODA starter compound, 0.36 g of 2,2′-bis(trifluoromethyl)benzidine, 1.67 g of 6FDA, and 14 mL of NMP were mixed for a period of 5 hours at room temperature in a N₂ atmosphere. The reaction liquid was then mixed for a period of 16 hours at 200° C. in a N₂ atmosphere. Sometime during this period, the PT precursor polymer formed in the reaction liquid was converted to the final PI polymer. Thereafter, the resulting reaction liquid was combined it with methanol and water, thereby precipitating a polymer. The polymer as precipitated was collected by filtration and then subjected to vacuum drying at a temperature of 50° C. The yield of the reaction was 86% by weight of the starter compound (2.84 g). Then the polymer was dissolved in NMP solvent such that its concentration in the solvent was 0.5 g/dL. The intrinsic viscosity of the polymer solution at 25° C. as measured by an Ostwald viscometer was 0.24 dL/g. The results of NMR and IR spectroscopy indicated that a PI polymer comprising the following repeating units had been formed:

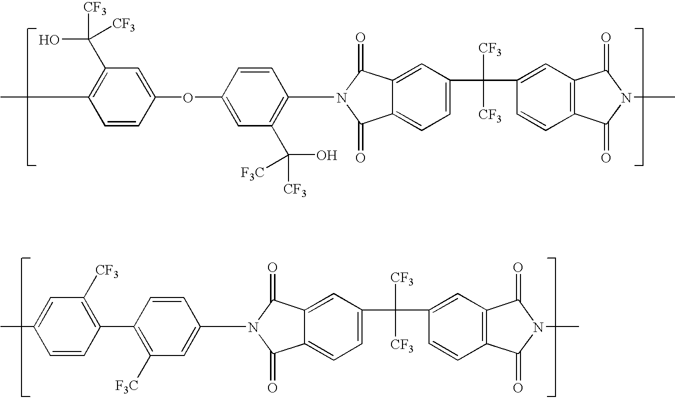

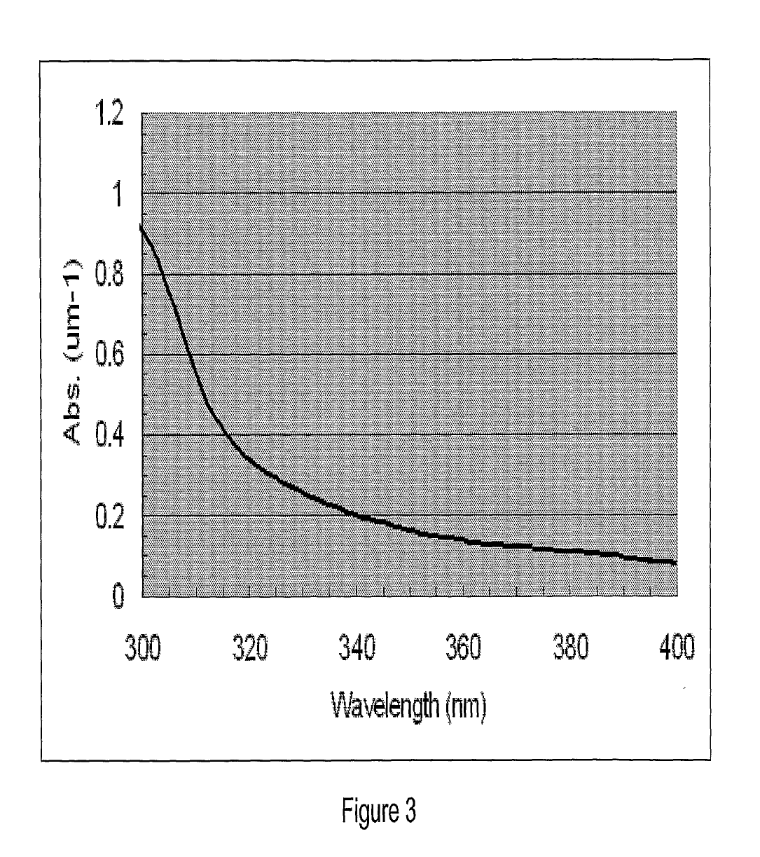

The PI polymer exhibited good solubility in DMF, γ-GBL, THF, PGMEA, and 0.25 N of TMAH aqueous solution. The dielectric constant value of the PI polymer as measured at a frequency of 1 MHz was determined to be 2.69. The absorbance of the PI polymer was also measured over a wide range of wavelengths. As shown in FIG. 3, the PI polymer exhibited very good absorbance data.

### Example 5

In a three-neck flask having a volume of 100 mL, 0.30 g of the PI precursor polymer obtained in Example 1, 0.07 g of di-tert-butyl dicarbonate, 0.01 g of pyridine, and 2 mL of NMP were mixed for a period of 16 hours at room temperature in a N₂ atmosphere. The reaction liquid was then combined with methanol and water, thereby precipitating a polymer. The polymer as precipitated was collected by filtration and then subjected to vacuum drying at room temperature. The yield of the reaction was 68% by weight of the PI precursor polymer (0.21 g). The results of NMR and IR spectroscopy indicated that a PI polymer comprising the following repeating units had been formed:

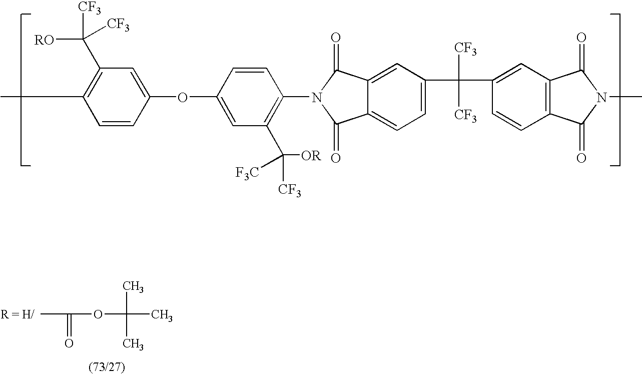

### Example 6

Diazonaphthoquinone (DNQ) as represented by the following was provided:

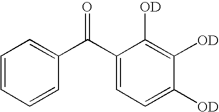

wherein D represents hydrogen or the sulfur-containing compound given below, with the molar ratio of H to sulfur-containing compound being approximately 34/66. This particular DNQ mixture is hereafter referred to “THBP” (which stands for trihydroxybenzophenone).

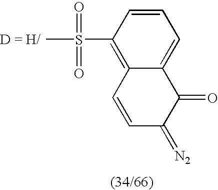

Within a vessel, 16 parts by weight of the PI polymer resin obtained in Example 2, 4 parts by weight of the THBP, and 80 parts by weight of PGMEA were mixed together. After homogeneously mixing these components, the resulting mixture was filtrated to prepare Sample A. Thus, the THBP was included at an amount of 4% by weight of the total mixture and at an amount of 20% by weight of the solids in the mixture.

Sample B was prepared in the same manner as sample A except for adding 14 parts by weight of the PI polymer resin obtained in Example 2 and 6 parts by weight of the THBP. Thus, the THBP was included at an amount of 6% by weight of the total mixture and at an amount of 30% by weight of the solids in the mixture.

Sample F was prepared in the same manner as sample A except for adding 16 parts by weight of the PI polymer resin obtained in Example 2 and 4 parts by weight of the THBP. Thus, the THBP was included at an amount of 4% by weight of the total mixture and at an amount of 20% by weight of the solids in the mixture.

Sample G was prepared in the same manner as Example 1 except for adding 15 parts by weight of the PI polymer resin obtained in Example 2 and 5 parts by weight of the THBP. Thus, the THBP was included at an amount of 5% by weight of the total mixture and at an amount of 25% by weight of the solids in the mixture.

Sample A was applied to a silicon substrate by means of spin coating at a rotation speed of 1,000 rpm for a period of 30 seconds. The silicon substrate was then heated at a temperature of 80° C. for a period of 3 minutes (soft bake). The film formed on the substrate had a thickness of 1.6 μm. Next, the surface of the film was covered by a mask plate having a pattern with size of line/space=150 μm/220 μm. Thereafter, the film was exposed to I-line radiation having a wavelength of 365 nm at a dose amount of 500 millijoules/squared centimeters (mJ/cm²). After the exposure, the film was developed in a TMAH aqueous solution having a concentration of 0.26 N. Then, the film was cured at a temperature of 300° C. for a period of 30 minutes (hard bake). The foregoing procedure of spin coating, soft baking, exposing, and developing, and hard baking was repeated for samples B, F, and G.

### Comparative Example 1

Sample C was prepared in the same manner as sample A except for adding 20 parts by weight of the PI polymer resin obtained in Example 2. No THBP was included in the mixture.

Sample D was prepared in the same manner as Example 1 except for adding 20 parts by weight of the PI polymer resin obtained in Example 5. No THBP was included in the mixture.

Sample E was prepared in the same manlier as Example 1 except for adding 20 parts by weight of the PI polymer resin obtained in Example 4. No THBP was included in the mixture.

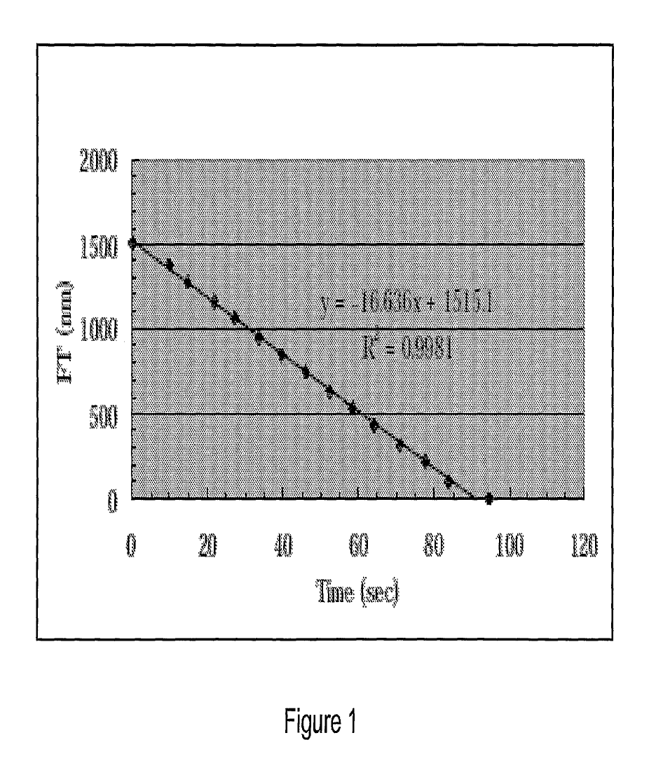

Sample C was applied to a silicon substrate by means of spin coating at a rotation speed of 1000 rpm for a period of 30 seconds. The silicon substrate was then heated at a temperature of 80° C. for a period of 3 minutes (soft bake). The film formed on the substrate had a thickness of 1.6 μm. Next, the surface of the film was covered by a mask plate having a pattern with size of line/space=150 μm/220 μm. Thereafter, the film was exposed to I-line radiation having a wavelength of 365 nm at a dose amount of 500 millijoules/squared centimeters (mJ/cm²). After the exposure, the film was developed in a TMAH aqueous solution having a concentration of 0.26 N. Then, the film was cured at a temperature of 300° C. for a period of 30 minutes (hard bake). FIG. 1 illustrates how the film thickness of sample C changed as a function of its developing time. The foregoing procedure of spin coating, soft baking, exposing, developing, and hard baking was repeated for samples D and E.

The dissolution rates (DRs) in TMAH aqueous solution were measured for samples A to G using a custom-made spectroscopic reflectometer based DR monitor. Table 2 summarizes the dissolution rates for the exposed and non-exposed regions. The dissolution rates for the exposed and non-exposed regions of samples A, B, F, and G were sufficiently different. For example, the dissolution rate of the exposed region of sample A was 12 times more than that of the non-exposed region. Also, the dissolution rate of the exposed region of sample G was 21 times more than the non-exposed region. Moreover, increasing the amount of THBP loading from sample A to sample B resulted in an increase in the dissolution rate of the exposed region but and a decrease in the dissolution rate of the unexposed region. Therefore, both an inhibition effect and a post-exposure acceleration effect were observed in the photosensitive films containing the PI polymer. The dissolution rates observed for comparative samples D and E were much lower than that of comparative sample C. Based on the foregoing, the PI polymers described herein would serve as good photodefinable films.

TABLE 1

| | DR in non-exposed | DR in exposed |
|---|---|---|
| Sample | region (nm/sec) | region (nm/sec) |
| Sample A | 10 | 120 |
| Sample B | 6 | 200 |
| Sample C | 16 | — |
| Sample D | 2 | — |
| Sample E | 4 | — |
| Sample F | 2 | 23 |
| Sample G | 2 | 43 |

### Example 7

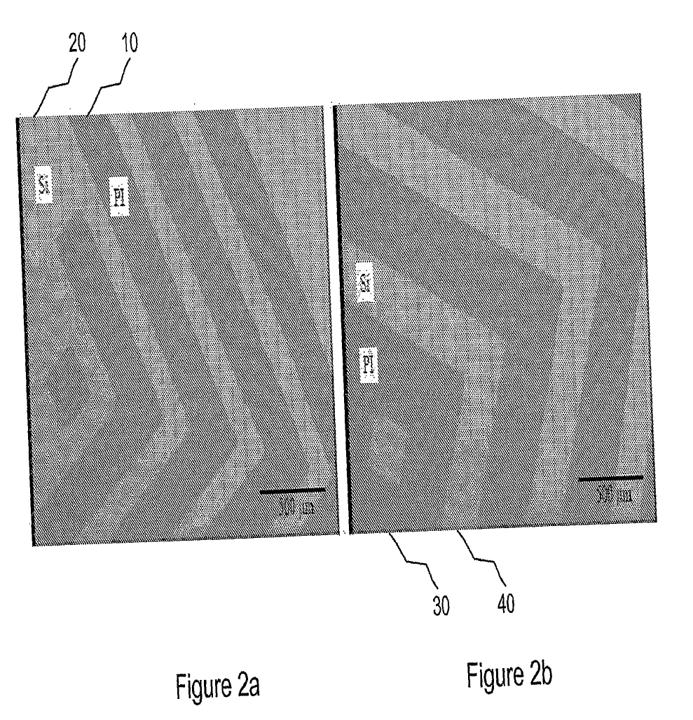

The procedure applied to sample A of Example 6 was repeated using a bright field mask and a dark field mask, thereby forming relief patterns in photosensitive PI films. The obtained relief patterns were then observed using an SEM. FIG. 2a shows the optical image of photosensitive PI film 10 upon silicon substrate 20 after it had been patterned using the bright field mask. FIG. 2b shows the optical image of photosensitive PI film 30 upon the silicon substrate 40 after it had been patterned using the dark field mask. The obtained pattern in these photosensitive films corresponded closely to the pattern of the mask used. For example, the lines of the patterned films were spaced apart by 150 μm.

While preferred embodiments have been shown and described, modifications thereof can be made by one skilled in the art without departing from the spirit and teachings of those embodiments. The embodiments described herein are exemplary only and are not intended to be limiting. Many variations and modifications of the embodiments are possible and are within the scope thereof. Use of the term “optionally” with respect to any element of a claim is intended to mean that the subject element is required, or alternatively, is not required. Both alternatives are intended to be within the scope of the claim.

Accordingly, the scope of protection is not limited by the description set out above but is only limited by the claims which follow, that scope including all equivalents of the subject matter of the claims. Each and every claim is incorporated into the specification as an embodiment. Thus, the claims are a further description and are an addition to the preferred embodiments. The discussion of a reference herein is not an admission that it is prior art to the embodiments described herein, especially any reference that may have a publication date after the priority date of this application. The disclosures of all patents, patent applications, and publications cited herein are hereby incorporated by reference, to the extent that they provide exemplary, procedural, or other details supplementary to those set forth herein.

What is claimed is:

1. A photosensitive composition comprising:
(a) a polymer comprising a repeating unit as represented by the following formula: 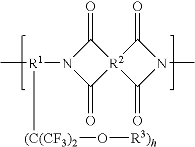
wherein R¹ comprises an aliphatic group, an alicyclic group, an aromatic group, a heterocyclic group, or combinations thereof,
wherein R² comprises an aliphatic group, an alicyclic group, an aromatic group, a heterocyclic group, or combinations thereof,
wherein R³ represents hydrogen or an organic group comprising a hydrophilic group, an acid-cleavable group, a base-cleavable group, a cross-linkable group, or combinations thereof, and
wherein h represents an integer of 1 or more; and
(b) a photosensitive additive.

2. The photosensitive composition of claim 1, wherein the photosensitive additive comprises a photosensitive dissolution inhibitor, a photoacid generator, a photobase generator, a photo-free radical generator, or combinations thereof.

3. The photosensitive composition of claim 2, wherein the photosensitive dissolution inhibitor is present in the photosensitive composition in an amount in a range of from about 0.01% to about 40% by total weight of the polymer and the photosensitive additive.

4. The photosensitive composition of claim 2, wherein the photoacid generator is present in the photosensitive composition in an amount in a range of from about 0.01% to about 20% by total weight of the polymer and the photosensitive additive.

5. The photosensitive composition of claim 2, wherein the photobase generator is present in the photosensitive composition in an amount in a range of from about 0.01% to about 20% by total weight of the polymer and the photosensitive additive.

6. The photosensitive composition of claim 2, wherein the photo-free radical generator is present in the photosensitive composition in an amount in a range of from about 0.01% to about 20% by total weight of the polymer and the photosensitive additive.

7. The photosensitive composition of claim 1, further comprising a thermal acid generator, a cross-linker, a photosensitizer, or combinations thereof.

8. The photosensitive composition of claim 7, wherein the thermal acid generator is present in the photosensitive composition in an amount in a range of from about 0.01% to about 20% by total weight of the polymer and the photosensitive additive.

9. The photosensitive composition of claim 7, wherein the cross-linker is present in the photosensitive composition in an amount in a range of from about 0.01% to about 40% by total weight of the polymer and the photosensitive additive.

10. The photosensitive composition of claim 7, wherein the photosensitizer is present in the photosensitive composition in an amount in a range of from about 0.01% to about 20% by total weight of the polymer and the photosensitive additive.

11. The photosensitive composition of claim 1, wherein R³ is represented by the following formula: 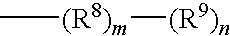
wherein R⁸ represents an organic group comprising from 1 to 40 carbon atoms,
wherein R⁹ comprises a hydrophilic group, a hydrophilic group protected by an acid-cleavable group, a hydrophilic group protected by a base-cleavable group, a hydrophilic group protected by a cross-linkable group, or combinations thereof,
wherein m represents an integer of 0 or 1, and
wherein n represents an integer of 1 or more.

12. The photosensitive composition of claim 11, wherein R⁹ is represented by one of the following formulas: 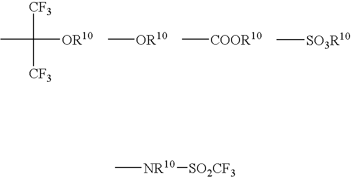
wherein R¹⁰ represents hydrogen or an organic group comprising an acid-cleavable group, a base-cleavable group, a cross-linkable group, or combinations thereof.

13. The photosensitive composition of claim 12, wherein R¹⁰ is represented by one of the following formulas: 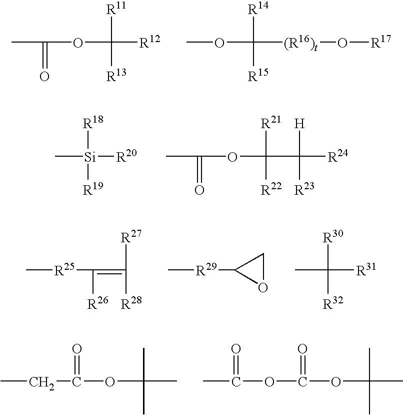
wherein R¹¹, R¹², and R¹³ each represents hydrogen or an organic group comprising from 1 to 40 carbon atoms,
wherein R¹⁴ and R¹⁵ each represents hydrogen or an organic group comprising from 1 to 40 carbon atoms,
wherein R¹⁶ and R¹⁷ each represents an organic group comprising from 1 to 40 carbon atoms,
wherein t represents an integer of 0 or 1,
wherein R¹⁸, R¹⁹, and R²⁰ each represents an organic group comprising from 1 to 40 carbon atoms,
wherein R²¹, R²², R²³, and R²⁴ each represents hydrogen or an organic group comprising from 1 to 40 carbon atoms,
wherein R²⁵ represents an organic group comprising from 1 to 40 carbon atoms,
wherein R²⁶, R²⁷ and R²⁸ each represents hydrogen or an organic group comprising from 1 to 40 carbon atoms,
wherein R³⁰, R³¹, and R³² each represents hydrogen or an organic group comprising from 1 to 40 carbon atoms, and
wherein R²⁹ represents an organic group comprising from 1 to 40 carbon atoms.

14. The photosensitive composition of claim 1, wherein
(i) R¹—(C(CF₃)₂—O—R³)ₕ is represented by the following formula: 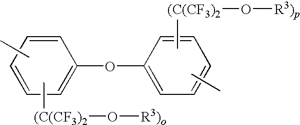
wherein o and p each represents an integer of 0, 1, 2, 3, or 4 and o+p>0, and
(ii) R² is represented by the following formula:

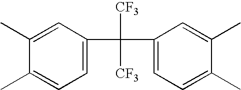

15. The photosensitive composition of claim 1, wherein
(i) R¹—(C(CF₃)₂—O—R³)ₕ is represented by the following formula: 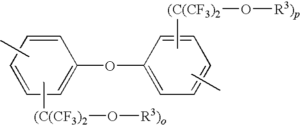
wherein o and p each represents an integer of 0, 1, 2, 3, or 4 and o+p>0, and
(ii) R² is represented by the following formula:

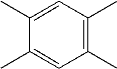

16. The photosensitive composition of claim 1, wherein R¹—(C(CF₃)₂—O—R³)ₕ is represented by the following formula: 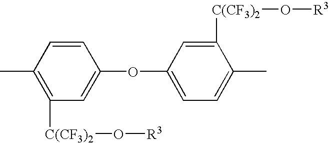
wherein R³ represents hydrogen or an organic group represented by one of the following formulas:

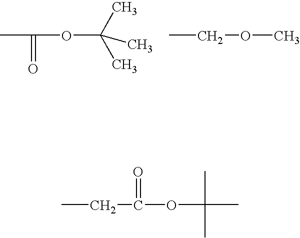

17. The photosensitive composition of claim 1, being made by a method comprising:
(a) forming a precursor polymer comprising a repeating unit represented by the following formula: 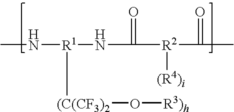
wherein R¹ comprises an aliphatic group, an alicyclic group, an aromatic group, a heterocyclic group, or combinations thereof,
wherein R² comprises an aliphatic group, an alicyclic group, an aromatic group, a heterocyclic group, or combinations thereof,
wherein R³ represents hydrogen or an organic group comprising a hydrophilic group, an acid-cleavable group, a base-cleavable group, a cross-linkable group, or combinations thereof,
wherein R⁴ comprises a hydrophilic group, a hydrophilic group protected by an acid-cleavable group, a hydrophilic group protected by a base-cleavable group, a hydrophilic group protected by a cross-linkable group, or combinations thereof,
wherein h represents an integer of 1 or more, and
wherein i represents an integer of 0, 1, or more; and
(b) converting the precursor polymer into the final polymer; and
(c) combining the precursor polymer with the photosensitive additive and a casting solvent.

18. The photosensitive composition of claim 17, wherein said converting comprises heating the precursor polymer at a thermal processing temperature in a range of from about 180° C. to about 320° C.

19. The photosensitive composition of claim 17, wherein said converting comprises heating the precursor polymer at a thermal processing temperature in a range of from about 250° C. to about 300° C.

20. The photosensitive composition of claim 17, wherein said converting comprises treating the precursor polymer with an acid catalyst or a dehydration agent.

21. The photosensitive composition of claim 17, further comprising combining the precursor polymer with a processing solvent before said converting, and separating out and purifying the final polymer after said converting.

22. The photosensitive composition of claim 17, wherein said forming the precursor polymer comprises polymerizing a substituted organic diamine compound and a dianhydride compound.

23. The photosensitive composition of claim 22, wherein the substituted organic diamine compound comprises hexafluoroisopropanol-substituted orthodiamine.

24. The photosensitive composition of claim 22, wherein the dianhydride compound comprises hexafluoro diamine.

25. The photosensitive composition of claim 1, wherein the photosensitive composition is a positive tone or a negative tone photodefinable material.

26. The photosensitive composition of claim 1, further comprising a casting solvent.

27. The photosensitive composition of claim 26, wherein the casting solvent comprises an amide, an ether ester, a ketone, an ester, a glycol ether, a hydrocarbon, an aromatic hydrocarbon, a fluorinated solvent, an alcohol, a carbonate, or combinations thereof.

28. The photosensitive composition of claim 26, wherein the casting solvent comprises N,N-dimethyl formamide, gamma-butyrolactone, propylene glycol methyl ether, propylene glycol methyl ether acetate, tetrahydrofuran, 1-methyl-2-pyrrolidinone, N,N-dimethylacetamide, cyclohexanone, methanol, acetone, or combinations thereof.

29. The photosensitive composition of claim 1, wherein the composition becomes more soluble in an alkaline aqueous developing solution when exposed to actinic light.

30. The photosensitive composition of claim 1, wherein the composition becomes less soluble in an alkaline aqueous developing solution when exposed to actinic light.

31. The photosensitive composition of claim 1, wherein the composition becomes less soluble in an organic developing solution when exposed to actinic light.

32. The photosensitive composition of claim 1, wherein the polymer exhibits an absorbance in a range of from about 0.01 μm⁻¹ to about 1.0 μm⁻¹ for ultraviolet light having a wavelength of 365 nm, wherein the polymer exhibits an absorbance in a range of from about 0.01 μm⁻¹ to about 1.0 μm⁻¹ for ultraviolet light having a wavelength of 405 nm, and wherein the polymer exhibits an absorbance in a range of from about 0.005 μm⁻¹ to about 1.0 μm⁻¹ for ultraviolet light having a wavelength of 436 nm.

33. The photosensitive composition of claim 1, wherein the polymer exhibits a dielectric constant in a range of from about 2.5 to about 3.5.

34. The photosensitive composition of claim 1, wherein the polymer exhibits a coefficient of thermal expansion in the range of from about 10 ppm/K to about 100 ppm/K.

35. A photosensitive composition comprising:
(a) a polymer comprising a repeating unit as represented by the following formula: 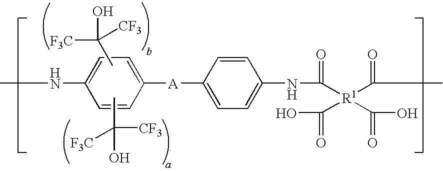
wherein A comprises nothing, oxygen, sulfur, nitrogen, or fluorine,
wherein a and b each represents an integer of 1, 2, 3, or 4, and
wherein R¹ comprises an alicyclic, aromatic, alkyl, or heterocyclic group substituted with nothing, an alkyl group, a fluoroalkyl group, a carboxyl group, a hydroxyl group, a cyano group, or combinations thereof; and
(b) a photosensitive additive.

36. The photosensitive composition of claim 35, wherein a=1, b=1, A is oxygen, and R¹ is represented by the following formula:

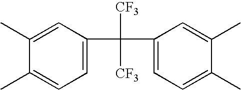

37. The photosensitive composition of claim 35, wherein the photosensitive additive comprises a photosensitive dissolution inhibitor, a photoacid generator, a photobase generator, a photo-free radical generator, or combinations thereof.

38. The photosensitive composition of claim 37, wherein the photosensitive dissolution inhibitor is present in the photosensitive composition in an amount in a range of from about 0.01% to about 40% by total weight of the polymer and the photosensitive additive.

39. The photosensitive composition of claim 37, wherein the photoacid generator is present in the photosensitive composition in an amount in a range of from about 0.01% to about 20% by total weight of the polymer and the photosensitive additive.

40. The photosensitive composition of claim 37, wherein the photobase generator is present in the photosensitive composition in an amount in a range of from about 0.01% to about 20% by total weight of the polymer and the photosensitive additive.

41. The photosensitive composition of claim 37, wherein the photo-free radical generator is present in the photosensitive composition in an amount in a range of from about 0.01% to about 20% by total weight of the polymer and the photosensitive additive.

42. The photosensitive composition of claim 35, further comprising a thermal acid generator, a cross-linker, a photosensitizer, or combinations thereof.

43. The photosensitive composition of claim 42, wherein the thermal acid generator is present in the photosensitive composition in an amount in a range of from about 0.01% to about 20% by total weight of the polymer and the photosensitive additive.

44. The photosensitive composition of claim 42, wherein the cross-linker is present in the photosensitive composition in an amount in a range of from about 0.01% to about 40% by total weight of the polymer and the photosensitive additive.

45. The photosensitive composition of claim 42, wherein the photosensitizer is present in the photosensitive composition in an amount in a range of from about 0.01% to about 20% by total weight of the polymer and the photosensitive additive.

46. The photosensitive composition of claim 35, wherein the photosensitive composition is a positive tone or a negative tone photodefinable material.

47. The photosensitive composition of claim 37, further comprising a casting solvent.

48. The photosensitive composition of claim 47, wherein the casting solvent comprises an amide, an ether ester, a ketone, an ester, a glycol ether, a hydrocarbon, an aromatic hydrocarbon, a fluorinated solvent, an alcohol, a carbonate, or combinations thereof.

49. The photosensitive composition of claim 47, wherein the casting solvent comprises N,N-dimethyl formamide, gamma-butyrolactone, propylene glycol methyl ether, propylene glycol methyl ether acetate, tetrahydrofuran, 1-methyl-2-pyrrolidinone, N,N-dimethylacetamide, cyclohexanone. methanol, acetone, or combinations thereof.

50. The photosensitive composition of claim 37, wherein the composition becomes more soluble in an alkaline aqueous developing solution when exposed to actinic light.

51. The photosensitive composition of claim 37, wherein the composition becomes less soluble in an alkaline aqueous developing solution when exposed to actinic light.

52. The photosensitive composition of claim 37, wherein the composition becomes less soluble in an organic developing solution when exposed to actinic light.

53. A photosensitive composition comprising:
(a) a copolymer comprising a repeating unit as represented by the following formula: 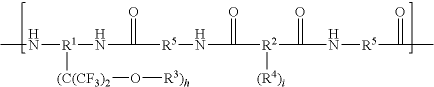
wherein R¹ comprises an aliphatic group, an alicyclic group, an aromatic group, a heterocyclic group, or combinations thereof,
wherein R² comprises an aliphatic group, an alicyclic group, an aromatic group, a heterocyclic group, or combinations thereof,
wherein R³ represents hydrogen or an organic group comprising a hydrophilic group, an acid-cleavable group, a base-cleavable group, a cross-linkable group, or combinations thereof,
wherein R⁴ comprises a hydrophilic group, a hydrophilic group protected by an acid-cleavable group, a hydrophilic group protected by a base-cleavable group, a cross-linkable group, or combinations thereof,
wherein R⁵ comprises an aliphatic group, an alicyclic group, an aromatic group, a heterocyclic group, or combinations thereof,
wherein h represents an integer of 1 or more, and
wherein i represents an integer of 0, 1, or more; and
(b) a photosensitive additive.

54. The photosensitive composition of claim 53, wherein R⁵ is represented by the following formula:

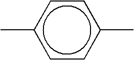

55. The photosensitive composition of claim 53, wherein the photosensitive additive comprises a photosensitive dissolution inhibitor, a photoacid generator, a photobase generator, a photo-free radical generator, or combinations thereof.

56. The photosensitive composition of claim 53, further comprising a thermal acid generator, a cross-linker, a photosensitizer, or combinations thereof.

57. The photosensitive composition of claim 53, further comprising a casting solvent.

58. A photosensitive composition comprising:
(a) a copolymer comprising a repeating unit as represented by the following formula: 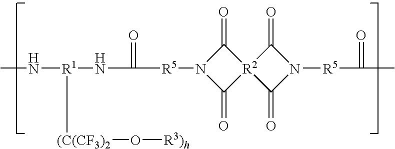
wherein R¹ comprises an aliphatic group, an alicyclic group, an aromatic group, a heterocyclic group, or combinations thereof,
wherein R² comprises an aliphatic group, an alicyclic group, an aromatic group, a heterocyclic group, or combinations thereof,
wherein R³ represents hydrogen or an organic group comprising a hydrophilic group, an acid-cleavable group, a base-cleavable group, a cross-linkable group, or combinations thereof,
wherein R⁵ comprises an aliphatic group, an alicyclic group, an aromatic group, a heterocyclic group, or combinations thereof, and
wherein h represents an integer of 1 or more; and
(b) a photosensitive additive.

59. The photosensitive composition of claim 58, wherein R⁵ is represented by the following formula:

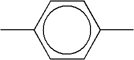

60. The photosensitive composition of claim 58, wherein the photosensitive additive comprises a photosensitive dissolution inhibitor, a photoacid generator, a photobase generator, a photo-free radical generator, or combinations thereof.

61. The photosensitive composition of claim 58, further comprising a thermal acid generator, a cross-linker, a photosensitizer, or combinations thereof.

62. The photosensitive composition of claim 58, further comprising a casting solvent.

63. A poly(benzoxazine-co-imide) composition comprising: 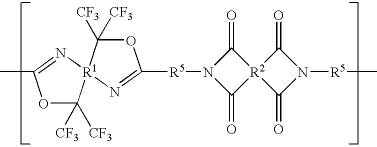
wherein R¹ comprises an aliphatic group, an alicyclic group, an aromatic group, a heterocyclic group, or combinations thereof,
wherein R² comprises an aliphatic group, an alicyclic group, an aromatic group, a heterocyclic group, or combinations thereof, and
wherein R⁵ comprises an aliphatic group, an alicyclic group, an aromatic group, a heterocyclic group, or combinations thereof.

64. The poly(benzoxazine-co-imide) composition of claim 63, wherein R⁵ is represented by the following formula:

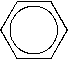

65. The poly(benzoxazine-co-imide) composition of claim 63, wherein:
(i) R⁵ is represented by the following formula: 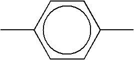
(ii) R² is represented by the following formula: 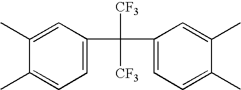
and
(iii) R¹ is represented by the following formula: [chemical structure]
